(19) United States
(12) Patent Application Publication
(10) Pub. No.: US 2009/0114154 A1
(43) Pub. Date: May 7, 2009

(54) PLASMA TREATMENT APPARATUS

(75) Inventors: Hitoshi Nakagawara, Tokyo (JP); Seiichi Igawa, Tokyo (JP); Katsuyoshi Igarashi, Tokyo (JP)

Correspondence Address: FITZPATRICK CELLA HARPER & SCINTO, 30 ROCKEFELLER PLAZA, NEW YORK, NY, 10112, US

(73) Assignee: Canon Anelva Corporation, Kawasaki-shi (JP)

(21) Appl. No.: 12/265,537

(22) Filed: Nov. 5, 2008

(30) Foreign Application Priority Data
Nov. 6, 2007 (JP) 2007-288736

(51) Int. Cl. C23C 16/513

(52) U.S. Cl. 118/723 ME

(57) ABSTRACT

The present invention provides a plasma treatment apparatus which has a plurality of UR-type plasma guns including reflected electron return electrodes, and can stably form a film having uniform film thickness and film quality. A plasma treatment apparatus according to one embodiment of the present invention sets an electric potential of at least one UR-type plasma gun at a floating potential. In one embodiment of the present invention, all UR-type plasma guns may be set at floating potentials. In other embodiment of the present invention, only one UR-type plasma gun may be grounded, and the other UR-type plasma guns may be set at floating potentials.

### CROSS-REFERENCES TO RELATED APPLICATIONS

This application claims the benefit of priority from Japanese Patent Application No. 2007-288736 filed Nov. 6, 2007, the entire contents of which is incorporated herein by reference.

### BACKGROUND OF THE INVENTION

1. Field of the Invention

The present invention relates to a plasma treatment apparatus including a plurality of plasma guns, each having a reflected electron return electrode.

2. Related Background Art

Conventionally, an insulation film is formed with an RF (Radio Frequency) sputtering method or an EB (Electron Beam) vapor deposition method. This is because an insulative substance is used as the film-forming material, electric charges are accumulated on the surface of the material, accumulated charges prevent the film from being formed, and accordingly a DC sputtering method which is usually used for forming a metal film cannot be used. The EB vapor deposition method heats and evaporates the film-forming material with electrons, so that the electric charges are accumulated on the surface of the material principally in the same way as in the DC sputtering method. However, the problem is improved by using high voltage and a little current, and changing a position to be irradiated by an electron beam on the material at a high speed.

However, a sufficient evaporation rate cannot be obtained from these techniques. For this reason, a device for forming a film has appeared which uses a new technique of using a plasma gun. One of these devices is a plasma display panel (PDP) using a magnesium oxide (MgO) film which is an insulation film as a protection film.

Because the plasma gun uses DC plasma similarly in the DC sputtering method, the electric charge is accumulated on the surface of the material of the insulative substance, and prevents the film from being formed. However, a plasma gun (hereinafter referred to as a UR-type plasma gun) which was invented by Mr. Uramoto in 1994 is provided with a reflected electron return electrode which was announced by Chugai Ro Co., Ltd. and Dai Nippon Printing Co., Ltd. in 1998, and can thereby secure a sufficient evaporation rate without preventing film-formation.

The above described UR-type plasma gun can be operated as is described in Japanese Patent Application Laid-Open No. H08-22802, and the technological content is incorporated in the present specification as the whole content is described.

The UR-type plasma gun includes a hollow cathode for generating a high-density plasma having an electron-emitting source provided therein, and a magnet for forming a magnetic field for introducing the plasma which is generated in the hollow cathode to a film-forming chamber. The reflected electron return electrode is arranged in the outlet of the UR-type plasma gun so as to surround a plasma beam.

A basic concept for the action of the film-forming device having the UR-type plasma gun including the reflected electron return electrode is to keep an electrified state of the film-forming material at a steady state by preventing one type of electric charges from continuing being accumulated on the film-forming material, and by reliably preparing a path for surely returning an electric current including secondary electrons which have been emitted from the film-forming material and the like, so-called, a reflected electron return current to a plasma-gun power-source. More specifically, an insulation material is charged with electricity in an early stage because of being exposed to plasma. On the other hand, so-called a reflected electron return current including secondary electrons or the like flows out from the surface of the charged insulation material. A state where the influent electron current balances the reflected electron return current is a steady state, and the state is maintained in principle. However, when the insulation film is deposited on a chamber wall or the like, through which electrons return, and a return path cannot be secured, the above described steady state cannot be maintained, and abnormal discharge or the like occurs in the film-forming chamber, which cause problems.

Therefore, in Japanese Patent Application Laid-Open No. H11-269636, the reflected electron return electrode is arranged in a plasma outgoing port side of the hollow cathode, which is a position apart from the film-forming chamber, so as to secure the return path and thereby secure a stable operation.

Here, the reflected electron return electrode means an electrode into which an electric current flows, which includes secondary electrons or the like generated by incident electrons/ions or the like in the plasma that has been generated by a plasma gun and has been incident on a vapor deposition material, and includes electrons or the like flowing in an opposite direction to the incident electron current.

By the way, there are the following documents on a prior art relating to the invention of this present application.
[Patent Document 1] Japanese Patent Application Laid-Open No. S55-148337
[Patent Document 2] Japanese Patent Application Laid-Open No. S59-027499
[Patent Document 3] Japanese Patent Application Laid-Open No. H07-161486
[Patent Document 4] Japanese Patent Application Laid-Open No. H08-22802
[Patent Document 5] Japanese Patent Application Laid-Open No. H08-45697
[Patent Document 6] Japanese Patent Application Laid-Open No. H08-319561
[Patent Document 7] Japanese Patent Application Laid-Open No. 2003-27231
[Patent Document 8] Japanese Patent Application Laid-Open No. H11-269636
[Patent Document 9] Japanese Patent Application Laid-Open No. 2000-219961
[Patent Document 10] Japanese Patent Application Laid-Open No. 2000-017431
[Patent Document 11] Japanese Patent Application Laid-Open No. 2000-017430
[Patent Document 12] Japanese Patent Application Laid-Open No. 2000-017429
[Non-patent document 1] Joshin Uramoto “Study for large-current and long-life cathode for ion plating”, Vacuum published by The Vacuum Society of Japan, vol. 25, p. 660-670, October, 1982
[Non-patent document 2] Joshin Uramoto “High-efficiency sheet plasma for large-area ion plating”, Vacuum published by The Vacuum Society of Japan, vol. 25, p. 719-726, November, 1982
[Non-patent document 3] Joshin Uramoto “Study on large-current H+ and D− ion sources by sheet plasma (I)”, Vacuum published by The Vacuum Society of Japan, vol. 27, p. 600-609, July, 1984
[Non-patent document 4] Joshin Uramoto “Study on large-current H+ and D− ion sources by sheet plasma (II)”, Vacuum published by The Vacuum Society of Japan, vol. 27, p. 610-616, July, 1984

Here, in order to form a film of an insulative substance on a PDP having a large area, it is not sufficient to use only one UR-type plasma gun, but it is necessary to use a plurality of the UR-type plasma guns including reflected electron return electrodes.

However, there has been a problem that when an insulation film is formed in a film-forming apparatus having the plurality of the UR-type plasma guns including the reflected electron return electrodes, a film having uniform film thickness and film quality cannot be stably formed.

### SUMMARY OF THE INVENTION

An object of the present invention is to be able to stably form a film with a uniform film thickness and film quality at a plasma treatment apparatus having a plurality of UR-type plasma guns including reflected electron return electrodes.

The following reasons, for instance, can be considered as the causes of the problem.

(1) Characteristics of the UR-type plasma gun vary with time.

(2) A film-forming ambient varies with time.

As a result of having made an extensive investigation on the above described problems, the present inventors found that the cause of the above described problem was based not on the above (1) or (2) but on the following reason.

That is to say, when an insulation film is formed in a conventional film-forming apparatus having a plurality of UR-type plasma guns including reflected electron return electrodes, for instance, when the apparatus has been used for a long period of time, there is a case where an insulative substance which has leaked out from the film-forming chamber deposits on the surface of one reflected electron return electrode. As a result, an electric resistance of the surface of the one reflected electron return electrode having the insulative substance deposited thereon increases. Therefore, an electric current flowing into the reflected electron return electrode decreases. The problem in such a state will now be described with reference to FIG. 8 illustratively. Specifically, a reflected electron return current 42a which returns to a reflected electron return electrode 16a of a plasma gun 10a having the insulation film thickly deposited thereon is only 80% of an incident electron current. On the other hand, a reflected electron return current 42b which returns to a reflected electron return electrode 16b of a plasma gun 10b having the insulation film thinly deposited thereon is 120% of the incident electron current. When the balance of these reflected electron return currents 42a and 42b varies, an impedance of each gun varies, simultaneously a self magnetic field generated by the reflected electron return current varies, and plasma in the film-forming chamber varies. As a result, such a problem occurs that a film having uniform film thickness and/or film quality cannot be stably formed. This occurs because even though there is excess or deficiency in the quantity of electrons flowing into each reflected electron return electrode, the plasma-gun power-source itself can stably operate in normal electrical wiring, since reflected electron return electrodes are connected to each other through a ground line 53 so that the quantity of the input current from a plasma-gun power-source matches the quantity of the output current into the plasma-gun power-source as is understood from FIG. 8.

As a result of having made an extensive investigation, the present inventors have found that the above described problems can be solved by setting the UR-type plasma gun including the reflected electron return electrode at a floating potential (by disconnecting gun from ground line).

A first aspect of the present invention is a plasma treatment apparatus for treating an object with plasma comprising a plurality of plasma guns, a plurality of reflected electron return electrodes which are arranged so as to correspond to the plurality of the plasma guns respectively, and a plurality of driving power-sources for the plurality of the plasma guns respectively, wherein electric potentials of at least one of the plurality of driving power-sources, the reflected electron return electrode which is electrically connected to the driving power-source, and a plasma gun which corresponds to the driving power-source are set at a floating potential.

A second aspect of the present invention is a plasma treatment apparatus for treating an object with plasma comprising a plasma-gun driving mechanism having a plasma gun, a reflected electron return electrode which is arranged so as to correspond to the plasma gun, and a driving power-source for the plasma gun, wherein the plasma treatment apparatus includes a plurality of the plasma-gun driving mechanisms, an electric circuit is constituted by at least the driving power-source and the reflected electron return electrode in each of the plasma-gun driving mechanisms, and electric circuits of the plurality of the plasma-gun driving mechanisms are insulated from each other.

A third aspect of the present invention is a film-forming apparatus, for forming a film on an object through plasma treatment comprising a plurality of plasma guns, a plurality of reflected electron return electrodes which are arranged so as to correspond to the plurality of the plasma guns respectively, and a plurality of driving power-sources for each of the plurality of the plasma guns, wherein electric potentials of at least one of the plurality of driving power-source, a reflected electron return electrode which is electrically connected to the driving power-source, and a plasma gun which corresponds to the driving power-source are set at a floating potential. Furthermore, a fourth aspect of the present invention is an insulation-film-forming apparatus for forming an insulation film on an object through plasma treatment comprising a plurality of plasma guns, a plurality of reflected electron return electrodes which are arranged so as to correspond to the plurality of the plasma guns respectively, and a plurality of driving power-sources for each of the plurality of the plasma guns, wherein electric potentials of at least one of the plurality of driving power-source, a reflected electron return electrode which is electrically connected to the driving power-source, and a plasma gun which corresponds to the driving power-source are set at a floating potential.

A film-forming apparatus having a plurality of UR-type plasma guns including reflected electron return electrodes according to the present invention can stably form an insulation film having uniform film thickness and/or film quality for a long period of time.

### BRIEF DESCRIPTION OF THE DRAWINGS

FIG. 1 is a side view of a schematic configuration of a film-forming apparatus according to Embodiment 1 of the present invention.

FIG. 2 is a perspective view illustrating an aspect in which an insulation film is formed with a film-forming apparatus according to Embodiment 1 of the present invention.

FIG. 3 is an explanatory drawing on the generation and control of plasma generated by a UR-type plasma gun which is used in Embodiment 1 of the present invention.

FIG. 4 is a circuit diagram in a schematic configuration of a film-forming apparatus according to Embodiment 1 of the present invention.

FIG. 5 is a view illustrating electron currents in a film-forming apparatus according to Embodiment 1 of the present invention.

FIG. 6 is a circuit diagram in a schematic configuration of a film-forming apparatus according to Embodiment 2 of the present invention.

FIG. 7 is a view illustrating electron currents in a film-forming apparatus according to Embodiment 2 of the present invention.

FIG. 8 is a view illustrating a configuration of a film-forming apparatus according to a conventional example and an electron current flowing in the apparatus.

### DETAILED DESCRIPTION OF THE PREFERRED EMBODIMENTS

Embodiments of the present invention will now be described below in detail with reference to the drawings. Components having the same functions in the drawings described in the present specification will be denoted with the same reference numerals, and repeated descriptions will be omitted.

An insulation-film-forming apparatus using a plurality of UR-type plasma guns including reflected electron return electrodes according to the embodiment in the present application will now be described below.

### Embodiment 1

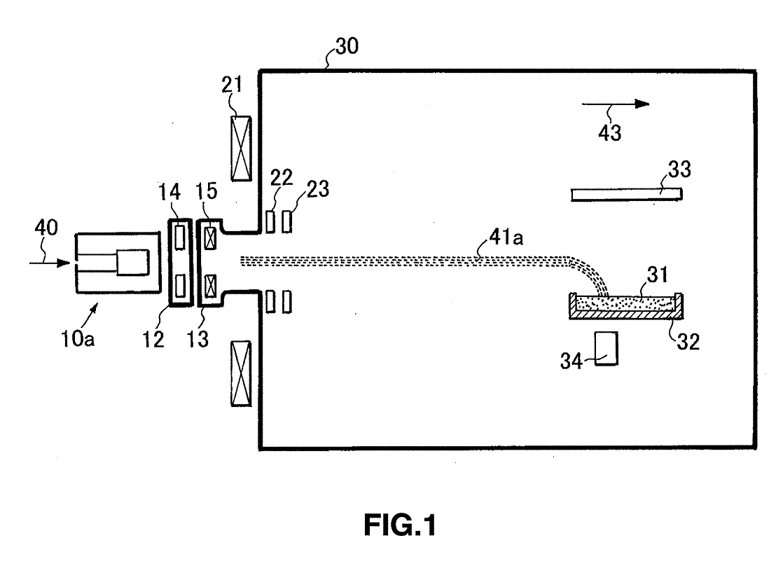

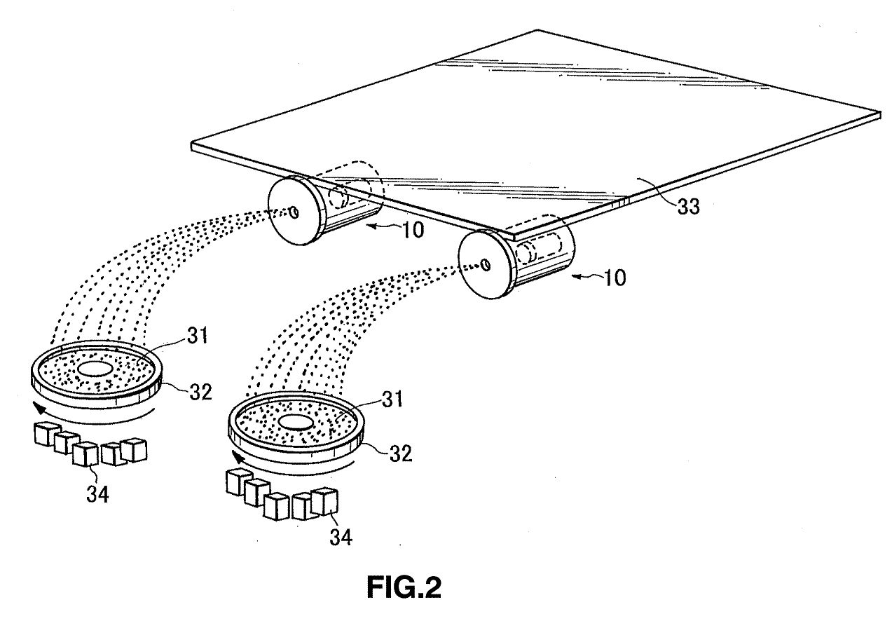

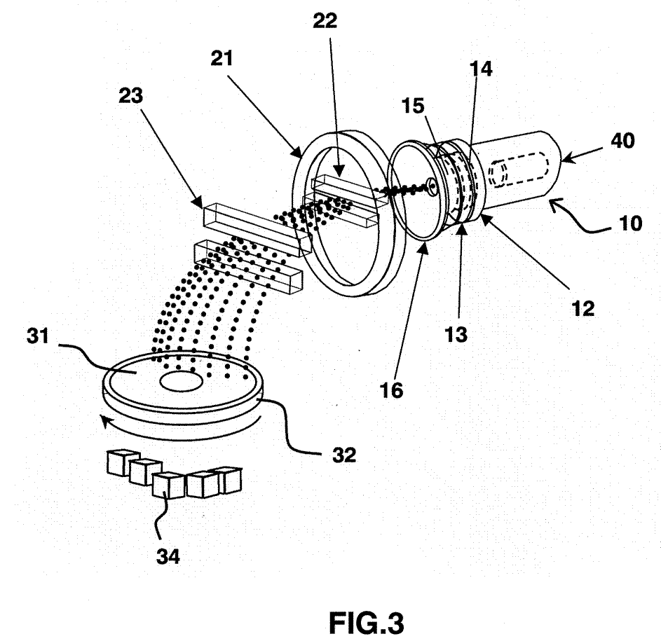

FIG. 1 is a side view of a schematic configuration of a film-forming apparatus according to Embodiment 1 of the present invention. FIG. 2 is a perspective view illustrating an aspect in which an insulation film is formed with the apparatus. However, in FIG. 2, a film-forming chamber and the like are omitted because FIG. 2 illustrates a view for describing the outline of the aspect in which the film is formed. FIG. 3 is an explanatory drawing on the generation and control of plasma generated by a UR-type plasma gun which is used in Embodiment 1.

In FIG. 1, a plasma gun 10a comprises an intermediate electrode 12 having an annular magnet 14, and an intermediate electrode 13 having an annular coil 15. A convergence coil 21 is arranged in between the plasma gun 10a and a film-forming chamber 30 which will be described later, so as to surround plasma discharged from the plasma gun 10a.

Though the configuration of the plasma gun 10a was described in FIG. 1, a plasma gun 10b also has the same configuration as the plasma gun 10a.

As is illustrated in FIG. 1, an evaporating material tray 32 which accommodates an evaporating material (MgO, for instance) 31 of an insulative substance therein is arranged in a lower part of the film-forming chamber 30 that is under a low pressure because of having been evacuated and is located downstream of plasma output from the plasma gun 10a. The evaporating material tray 32 is in an electrically floating state. In addition, an anode magnet 34 is arranged in a lower part of the evaporating material tray 32. A substrate 33 to be subjected to film-forming treatment (glass substrate for display, for instance) is arranged in an upper part in the film-forming chamber 30 so as to face to the evaporating material tray 32. The substrate 33 is continuously transported by an unshown substrate holder so as to form a predetermined space between the substrate 33 and the evaporating material tray 32, as shown in an arrow 43. Sheeting magnets 22 and 23 for converting the plasma into a sheet shape are provided in the vicinity of a portion at which the above described film-forming chamber 30 is connected with the plasma gun 10a.

When an evaporating material in the evaporating material tray 32 is irradiated with an electron current 41a, the evaporating material is scattered in the film-forming apparatus, deposits on the substrate 33, and forms a film on the substrate 33.

FIG. 2 is a perspective view illustrating an aspect in which an insulation film is formed with the film-forming apparatus, and illustrating an example of using two plasma guns in the present embodiment. However, in the figure, a film-forming chamber and the like are omitted because the figure illustrates a view for describing the outline of the present invention. Two plasma guns are arranged in parallel so as to form a uniform film on a large-area substrate.

FIG. 3 is an explanatory drawing for describing the generation and control of plasma generated by one plasma gun 10 of the above two plasma guns. In the present embodiment, a reflected electron return electrode 16 is arranged in the output side of the plasma gun 10, as is illustrated in FIG. 3. In the plasma gun, Ar 40 is introduced, and the pressure is kept at approximately several hundreds Pa. When an unshown electron-emitting source (LaB₆, for instance) in a cathode is heated, the electron-emitting source generates a large quantity of thermal electrons. The generated thermal electrons are accelerated toward intermediate electrodes 12 and 13 which are anodes 12 and 13. During traveling between the electron-emitting source and the electrodes, the electron collides with a neutral gas, ionizes the neutral gas, and generates plasma. The generated plasma is introduced into a magnetic field axially formed by an annular magnet 14 built in a first intermediate electrode 12 and an annular coil 15 built in a second intermediate electrode 13, and enters into a film-forming chamber 30 which has been exhausted, for instance, into several tenths of a Pascal. The plasma having flowed from the UR-type plasma gun is converged by a convergence coil 21. The converged plasma is sheeted by two sheeting magnets 22 and 23. The sheeted plasma is led by an anode magnet 34 which is placed in the rear surface of an evaporating material tray 32, is incident into an evaporating material 31, and heats the evaporating material 31. As a result, the evaporating material 31 in a heated portion evaporates, reaches a substrate 33 which is held by a not-shown substrate holder and moves in a direction shown by an arrow 43, and forms a film on the surface of the substrate 33. In addition, the material tray 32 is rotated by an unshown rotation mechanism so that the evaporating material 31 can be uniformly evaporated.

However, when an insulation-film-forming apparatus using the above described UR-type plasma gun has been used for a long period of time, for instance, there may be a case as is described in a column of “SUMMARY OF THE INVENTION”, in which an electric current flowing into the reflected electron return electrode of the UR-type plasma gun including the reflected electron return electrode becomes different from that of each plasma gun, which consequently makes the plasma ununiform, and finally impairs the uniformity of the film thickness and/or the film quality.

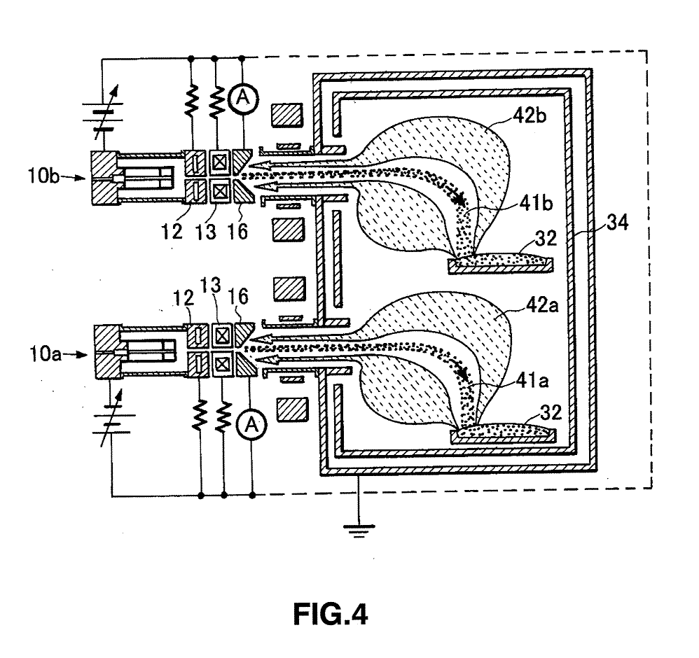

For this reason, in Embodiment 1 according to the present invention, all reflected electron return electrodes and UR-type plasma guns including the electrodes are set at floating potentials. In other words, a circuit including at least a driving power-source of the plasma gun and the reflected electron return electrode 16 is set at a floating state in each plasma gun. FIG. 4 illustrates the circuit diagram. Here, the arrow expresses the flow of electrons which flow in an opposite direction to the direction of an electric current. The arrow in the drawing expresses a direction of the electron flow hereafter, unless otherwise specified. However, lead lines for illustrating a portion are excluded. In addition a word, electron current, in the specification, claims and drawings means a flow of charged particles flowing in the opposite direction to the direction of the electric current, which is used in normal meaning.

In FIG. 4, each of plasma guns 10a and 10b is constituted so as to include at least a driving power-source for the plasma gun and the reflected electron return electrode 16, and the circuits for the plasma guns which have been constituted in this way are set at a floating state. In other words, the above described circuits for respective plasma guns 10a and 10b are electrically insulated from each other (being electrically disconnected).

By the way, “driving power-source for plasma gun” in the specification means a power source that is connected between a cathode including the electron-emitting source and a reflected electron return electrode, the plasma gun including the driving power-source for plasma gun.

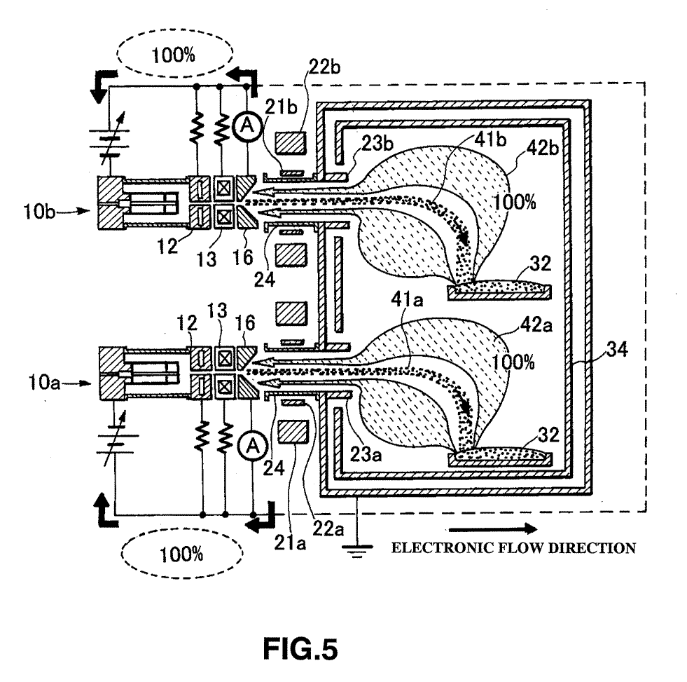

A working state of the plasma treatment apparatus at this time is illustrated in FIG. 5. Here, the evaporating material tray 32 is depicted in a state of being rotated by 90 degrees around a horizontal axis, for description.

Structures arranged in a downstream of electron current from the reflected electron return electrode, specifically, a short pipe 24, a second sheeting magnet 23 and a shield 34 for covering the inner wall of the film-forming chamber 30 are set at an electrically floating potential, and a net current does not flow into the components.

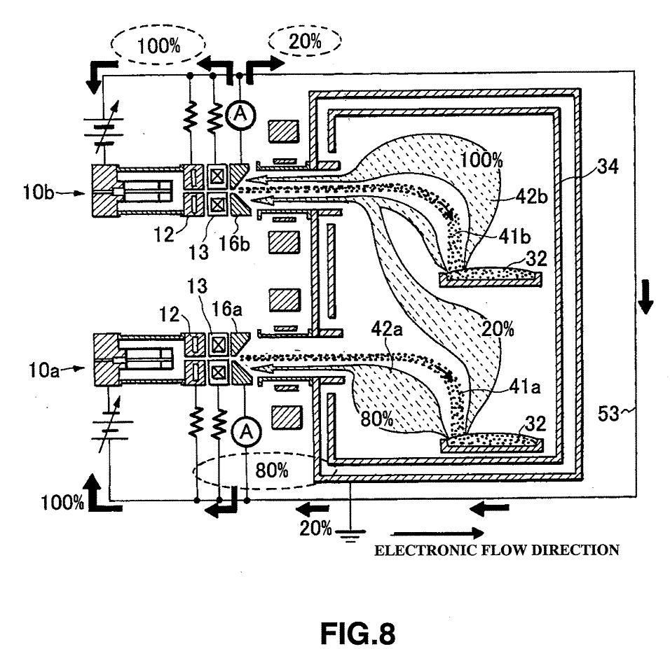

All structures which are arranged in a downstream of electron current from the reflected electron return electrode are preferably set at a floating potential electrically. In other words, potentials of members existing in a path for plasma to pass from the plasma gun to a member for holding the evaporating material are preferably set at a floating potential in the plasma treatment apparatus. Then, the reflected electron return current generated from the discharge electron current results in flowing into the reflected electron return electrode 16. The driving power-source which is connected to the plasma gun and the reflected electron return electrode is set at a floating potential, so that a discharge electron current 41 discharged from one particular plasma gun is forced to return back to the same particular plasma gun. In other words, it cannot happen that the discharge electron current flows into an adjacent reflected electron return electrode, as was described in “SUMMARY OF THE INVENTION” with reference to FIG. 8. As a result, the plasma is uniformized, and a film to be formed thereby obtains uniform film thickness and/or film quality.

Thus, in the present embodiment, a potential of each electric circuit including at least a driving power-source of a plasma gun and a reflected electron return electrode is set at a floating potential, even though there are a plurality of plasma guns, so that the reflected electron return current caused by a discharge electron current generated from each plasma gun returns to the reflected electron return electrode corresponding to the plasma gun from which the discharge electron current has been supplied. In other words, electrical circuits of the plurality of the plasma guns including at least the driving power-source of the plasma gun and the reflected electron return electrode are set at a floating state respectively, and are not electrically connected with each other, so that almost all of the reflected electron return current generated from the plasma of a certain plasma gun can return to the reflected electron return electrode of the above described plasma gun without flowing to reflected electron return electrodes of other plasma guns, according to the law of charge conservation. Therefore, even when the degree of deposition of an insulation film is different among each reflected electron return electrode, the plasma treatment apparatus can return the reflected electron return current to the reflected electron return electrode without excess or deficiency with respect to the discharge electron current. Thereby, the plasma treatment apparatus can realize the uniformization of the plasma which outflows from each plasma gun.

The plasma treatment apparatus according to the present embodiment also can match the quantity of the current flowing out from a plasma-gun power-source and the quantity of the current flowing into the plasma-gun power-source for each plasma gun, because of returning the reflected electron return current to the reflected electron return electrode without excess or deficiency with respect to the discharge electron current, as is described above. Therefore, the plasma treatment apparatus can steadily operate each plasma gun without providing a compensation mechanism such as the ground line 53 in FIG. 8.

In the present embodiment, it is essential to make almost all of reflected electron return currents that have been generated from the plasma (discharge electron current), which has been output from a certain plasma gun and has been incident on an evaporating material, incident (return) on a reflected electron return electrode corresponding to the above described certain plasma gun without making the reflected electron return currents incident on other plasma guns. For this purpose, in the present embodiment, a potential of a plasma gun including a reflected electron return electrode which is arranged in a plasma discharging port side is set at a floating potential.

However, when it is considered to be important in the present invention to return almost all of the reflected electron return currents to the reflected electron return electrode associated with the plasma gun of a supply source, as is described above, the above described effect can be obtained by setting a potential of at least the reflected electron return electrode which is electrically connected with the plasma gun and a driving power-source of the plasma gun, at a floating potential.

Therefore, in the present embodiment, a potential of an electrical circuit including at least a plasma gun, a reflected electron return electrode and a driving power-source of the plasma gun is set at least at a floating potential.

The configuration described in FIG. 3 to FIG. 5 is a preferable form because the reflected electron return electrode is provided in the vicinity of a discharge end of the plasma gun, which can reduce an amount of an evaporating material that evaporates and deposits on the reflected electron return electrode. However, what is important in the present embodiment is to return almost all of each reflected electron return current to a predetermined reflected electron return electrode, so that the arranged position of the reflected electron return electrode is not essential. Accordingly, the position of the reflected electron return electrode to be arranged is not limited to the above described position, but may be any place, for instance, in a film-forming chamber or the like. In other words, the position of the reflected electron return electrode to be arranged may be any place, as long as the reflected electron return electrode is electrically connected with a driving power-source of the corresponding plasma gun.

Furthermore, in the present embodiment, a plasma-gun driving mechanism is formed by at least a plasma gun, a reflected electron return electrode for returning a reflected electron return current which has been generated by plasma discharged from the plasma gun and a driving power-source for the above described plasma gun. In the present embodiment, a plurality of plasma-gun driving mechanisms shall be formed because a plurality of plasma guns are prepared. Here, it is important to constitute electric circuits including at least the plasma guns, the reflected electron return electrodes and the driving power-sources in each plasma-gun driving mechanism, and to insulate the electric circuits from each other.

Accordingly, the number of the reflected electron return electrode may be more than one, as long as the electric circuit is constituted in one plasma-gun driving mechanism so as to satisfy the above described conditions.

### Embodiment 2

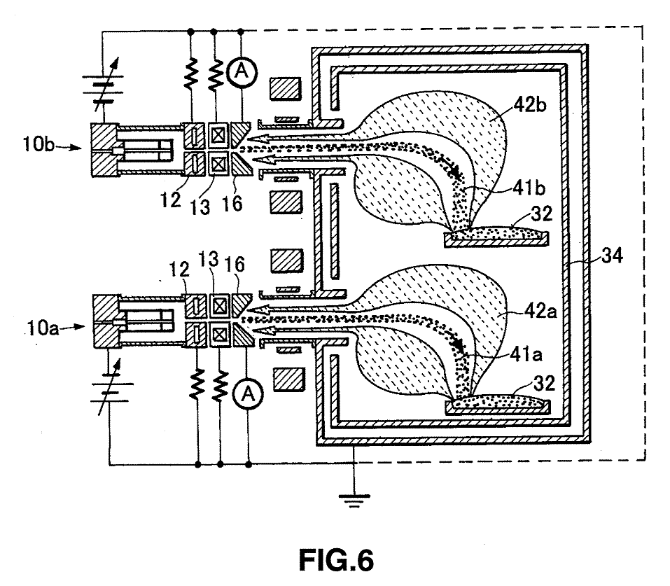

In Embodiment 2 as well according to the present invention, a plurality of UR-type plasma guns including reflected electron return electrodes are used, but one of the UR-type plasma guns including the reflected electron return electrodes is grounded, and all other UR-type plasma guns including the reflected electron return electrodes are set at a floating state (not grounded). FIG. 6 illustrates the circuit diagram.

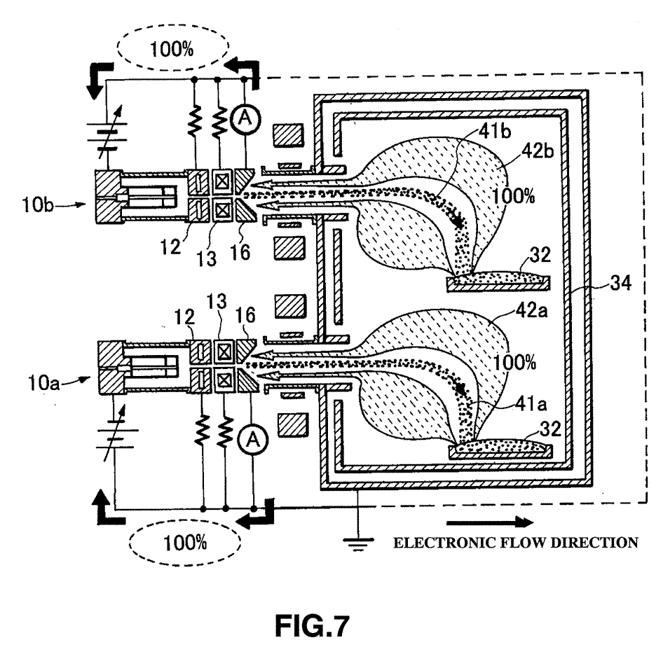

A working state of the plasma treatment apparatus at this time is illustrated in FIG. 7. Here, an evaporating material tray 32 is depicted in a state of being rotated by 90 degrees with respect to a horizontal line, for description, similarly to Embodiment 1 of the present invention. Structures arranged in downstream of electron current from the reflected electron return electrode, specifically, a short pipe 24, a second sheeting magnet 23 and a shield 34 for covering the inner wall of a film-forming chamber 30 are set at an electrically floating potential, which is also similar to Embodiment 1. Because any of reflected electron return electrodes is not connected to the others, the return currents to the plasma-gun power-sources cannot compensate their excess or deficiency with each other, as is illustrated in FIG. 7. Therefore, a discharge electron current 41 which has been discharged from a certain particular plasma gun is forced to return to a corresponding reflected return electrode. In other words, it cannot happen that the discharge electron current flows into an adjacent reflected electron return electrode, as was described in “SUMMARY OF THE INVENTION” with reference to FIG. 8. As a result, the plasma is uniformized, and a film to be formed thereby obtains uniform film thickness and/or film quality.

The potential of the plasma relating to the grounded one UR-type plasma gun including the reflected electron return electrode becomes nearly a ground level. Plasmas relating to separate UR-type plasma guns including reflected electron return electrodes acquire the same potential because the plasmas contact each other in the film-forming chamber. Therefore, all the potentials of the plasmas relating to the UR-type plasma guns including the reflected electron return electrodes settle in nearly a ground level. Accordingly, the potential of the whole plasma becomes stable.

### Embodiment 3

An insulation-film-forming apparatus according to Embodiment 3 of the present invention has the plurality of the UR-type plasma guns including the reflected electron return electrodes as described above, and sets the potential of a certain particular UR-type plasma gun including a reflected electron return electrode at a floating potential.

As is understood from the above described description, the above described plasma treatment apparatus having the plurality of the UR-type plasma guns including the reflected electron return electrodes sets the potential of the certain particular UR-type plasma gun including the reflected electron return electrode at the floating potential, and can thereby prevent reflected return electron currents of adjacent UR-type plasma guns from flowing into the reflected electron return electrode, or the electron current relating to the UR-type plasma gun from flowing into the adjacent reflected electron return electrodes. Therefore, insofar as the plasma gun is concerned, the electron current which has flowed out from the UR-type plasma gun returns back to the reflected electron return electrode of the plasma gun. The configuration according to the present embodiment is effective when being applied to a UR-type plasma gun including a reflected electron return electrode corresponding to a plasma which easily causes interference with a plasma generated from an adjacent plasma gun, in the configuration of the insulation-film-forming apparatus.

In the above described embodiment, a case of using two UR-type plasma guns was described, but it goes without saying that the embodiment can be also applied to an insulation-film-forming apparatus using three or four UR-type plasma guns.

A plasma treatment apparatus for forming an insulation film was described in the present specification, but the plasma treatment apparatus can be applied to a general process using plasma such as surface treatment for a large-area substrate like ion plating.

In addition, the present invention can be applied not only to the UR-type plasma gun but also a general plasma gun having the reflected electron return electrode.

In the above, preferred embodiments according to the present application were described with reference to the attached drawings, but the present invention is not limited to the embodiments, and can be modified into various aspects within the technical scope which is construed from the description in the claims.

What is claimed is:

1. A plasma treatment apparatus for treating an object with plasma comprising:
a plurality of plasma guns;
a plurality of reflected electron return electrodes which are arranged so as to correspond to the plurality of the plasma guns respectively; and
a plurality of driving power-sources for each of the plurality of the plasma guns, wherein
electric potentials of at least one of the plurality of driving power-sources, the reflected electron return electrode which is electrically connected to the driving power-source, and a plasma gun which corresponds to the driving power-source are set at a floating potential.

2. The plasma treatment apparatus according to claim 1, wherein electric potentials of all of the plurality of the driving power-sources, and plasma guns and reflected electron return electrodes which are electrically connected to each of the plurality of the driving power-sources, are set at floating potentials.

3. The plasma treatment apparatus according to claim 1, wherein
one of the plurality of the driving power-sources, and a plasma gun and a reflected electron return electrode which are electrically connected to the one of the plurality of the driving power-sources are grounded, and
electric potentials of the other driving power-sources, and plasma guns and reflected electron return electrodes which are electrically connected to each of the other driving power-sources, are set at a floating potential.

4. The plasma treatment apparatus according to claim 1, wherein the plasma gun is a UR-type plasma gun.

5. The plasma treatment apparatus according to claim 1 further comprising a holding member for holding an evaporating material, which is arranged downstream of the plasma that has been output from the plasma gun, with respect to the plasma gun, wherein
potentials of members existing in a path for the plasma to pass from the plasma gun to the holding member are set at a floating potential.

6. A plasma treatment apparatus for treating an object with plasma comprising:
a plasma-gun driving mechanism having a plasma gun, a reflected electron return electrode which is arranged so as to correspond to the plasma gun, and a driving power-source for the plasma gun, wherein
the plasma treatment apparatus includes a plurality of the plasma-gun driving mechanisms,
an electric circuit is constituted by at least the driving power-source and the reflected electron return electrode in each of the plasma-gun driving mechanisms, and
electric circuits of the plurality of the plasma-gun driving mechanisms are insulated from each other.

7. A film-forming apparatus for forming a film on an object through plasma treatment comprising:
a plurality of plasma guns;
a plurality of reflected electron return electrodes which are arranged so as to correspond to the plurality of the plasma guns respectively; and
a plurality of driving power-sources for each of the plurality of the plasma guns, wherein
electric potentials of at least one of the plurality of driving power-source, a reflected electron return electrode which is electrically connected to the driving power-source, and a plasma gun which corresponds to the driving power-source are set at a floating potential.

8. The film-forming apparatus according to claim 7, wherein a film of magnesium oxide (MgO) is formed.

9. An insulation-film-forming apparatus for forming an insulation film on an object through plasma treatment, including
a plurality of plasma guns;
a plurality of reflected electron return electrodes which are arranged so as to correspond to the plurality of the plasma guns respectively; and
a plurality of driving power-sources for each of the plurality of the plasma guns, wherein
electric potentials of at least one of the plurality of driving power-source, a reflected electron return electrode which is electrically connected to the driving power-source, and a plasma gun which corresponds to the driving power-source are set at a floating potential.

10. The insulation-film-forming apparatus according to claim 9, wherein the insulation film is formed from magnesium oxide (MgO).
